(19) United States
(12) Patent Application Publication
(10) Pub. No.: US 2012/0033361 A1
(43) Pub. Date: Feb. 9, 2012

(54) ELECTRONIC DEVICE

(75) Inventor: TUNG-CHUN TSAI, Tu-Cheng (TW)

(73) Assignee: HON HAI PRECISION INDUSTRY CO., LTD., Tu-Cheng (TW)

(21) Appl. No.: 13/030,355

(22) Filed: Feb. 18, 2011

(30) Foreign Application Priority Data
Aug. 9, 2010 (CN) 201010248395.9

(51) Int. Cl. H05K 7/00

(52) U.S. Cl. 361/679.01

(57) ABSTRACT

An electronic device includes a supporting device, a mounting member attached to the support member, an enclosure and a positioning component. The positioning component includes a first connecting portion, a second connecting portion and a clipping portion connected to the first connecting portion and the second connecting portion. The first connecting portion, the second connecting portion and the clipping portion define an accommodating space. The positioning component is attached to the enclosure, and a corner of the mounting member is received in the accommodating space of the positioning component, for preventing the enclosure from disengaging from the mounting member.

### BACKGROUND

1. Technical Field

The present disclosure relates to electronic devices, more particularly an electronic device with an enclosure supported by a supporting device.

2. Description of Related Art

In an all-in-one (AIO) device, a host of AIO device includes a plurality of electronic components received in an enclosure of AIO device. A lot of screws, typically screw the enclosure to a support device, that is very laborious and time-consuming.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device in accordance with an embodiment.

FIG. 2 is an isometric view of a positioning component of FIG. 1.

FIG. 3 is similar to FIG. 1, but shows two positioning components secured to a host.

FIG. 4 is an assembled view of FIG. 1, showing in a different aspect.

FIG. 5 is similar to FIG. 4, but shows in a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

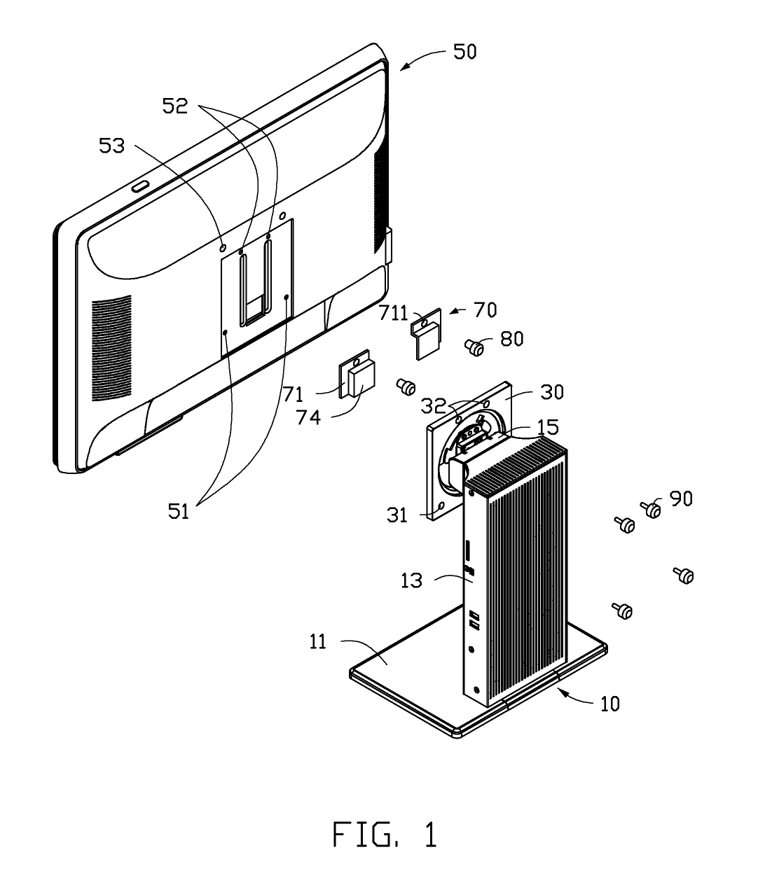

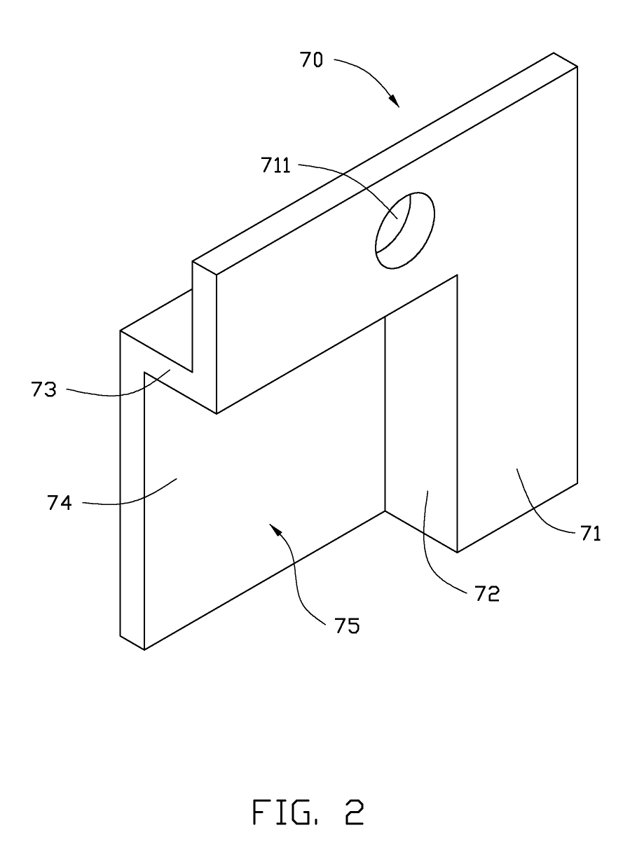

Referring to FIGS. 1 and 2, an electronic device in accordance with an embodiment includes a supporting device 10, a mounting member 30 attached to the front of the supporting device 10, an enclosure 50 secured to the mounting member 30, and two positioning components 70 attached to the back of the enclosure 50. In one embodiment, the electronic device is an AIO device.

The supporting device 10 includes a base 11 and a shaft 13 connected to the base 11. An extending portion 15 extends from a top end of the shaft 13 and is attached to the mounting member 30. In one embodiment, the shaft 13 is substantially perpendicular to the base 11 and the extending portion 15.

Two first mounting holes 31 (only one is shown in FIG. 1) are defined in two bottom corners of the mounting member 30. Two second mounting holes 32 are defined in the top portion of the mounting member 30. In one embodiment, the two first mounting holes 31 and the two second mounting holes 32 are arranged in four corners of an isosceles trapezoid pattern.

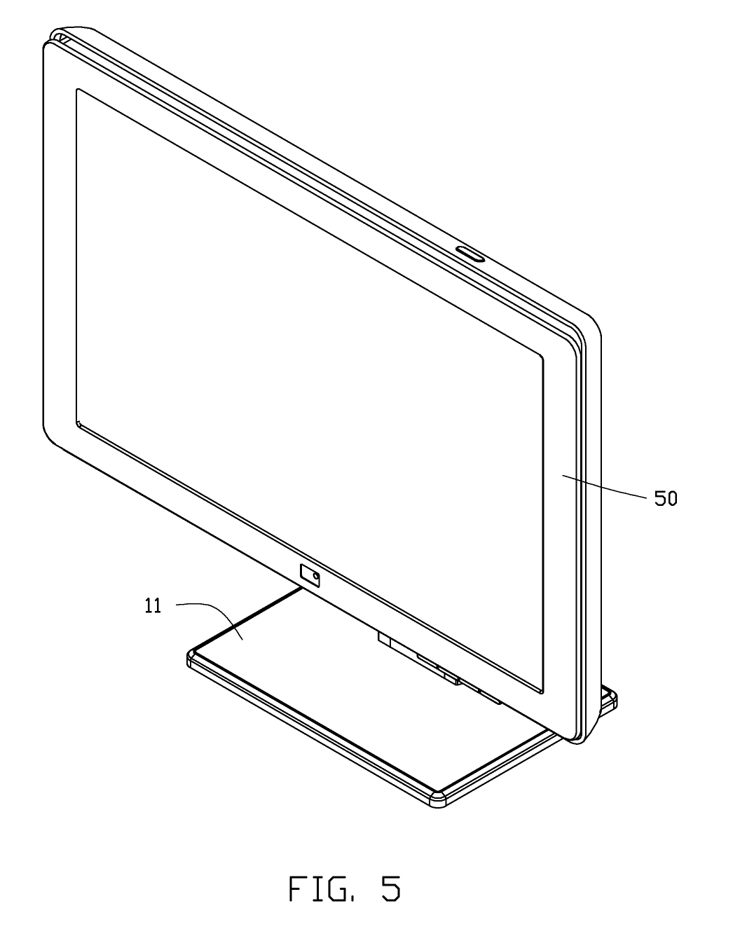

A display (shown in FIG. 5) is secured to the front of the enclosure 50, and a plurality of electronic components (not shown) is secured to the back of the enclosure 50. In one embodiment, the electronic components may be, for instance, a circuit, a CPU, an electronic card, or a single in-line memory module (SIMM). Two first securing holes 51, two second securing holes 52 and two fixing holes 53 are defined in a second area of the back of the enclosure 50. The two first securing holes 51 correspond to the two first mounting holes 31, and the two second securing holes 52 correspond to the two second mounting holes 32.

Referring to the FIG. 2, each positioning component 70 includes a securing portion 71, a first connecting portion 72, a second connecting portion 73, and a clipping portion 74 connected to the first and second connecting portions 72, 73. A retaining hole 711 is defined in the securing portion 71, corresponding to the fixing hole 53 of the enclosure 50. In one embodiment, the first and second connecting portions 72, 73 are substantially perpendicular to each other. The first and second connecting portions 72, 73 are substantially perpendicular to the securing portion 71 and the clipping portion 74. The clipping portion, the first connecting portion 72 and the second connecting portion 73 form an accommodating space 75 for receiving the mounting member 30.

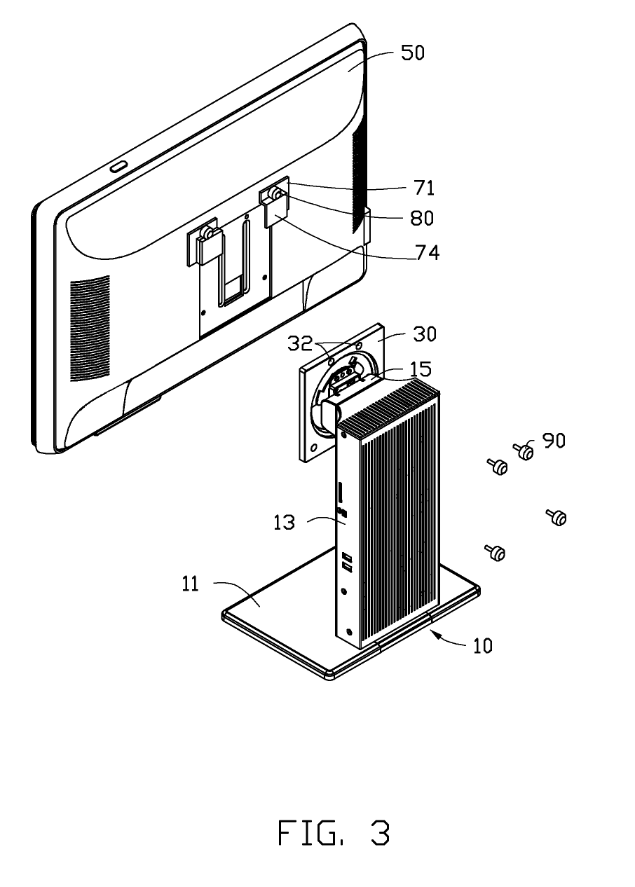

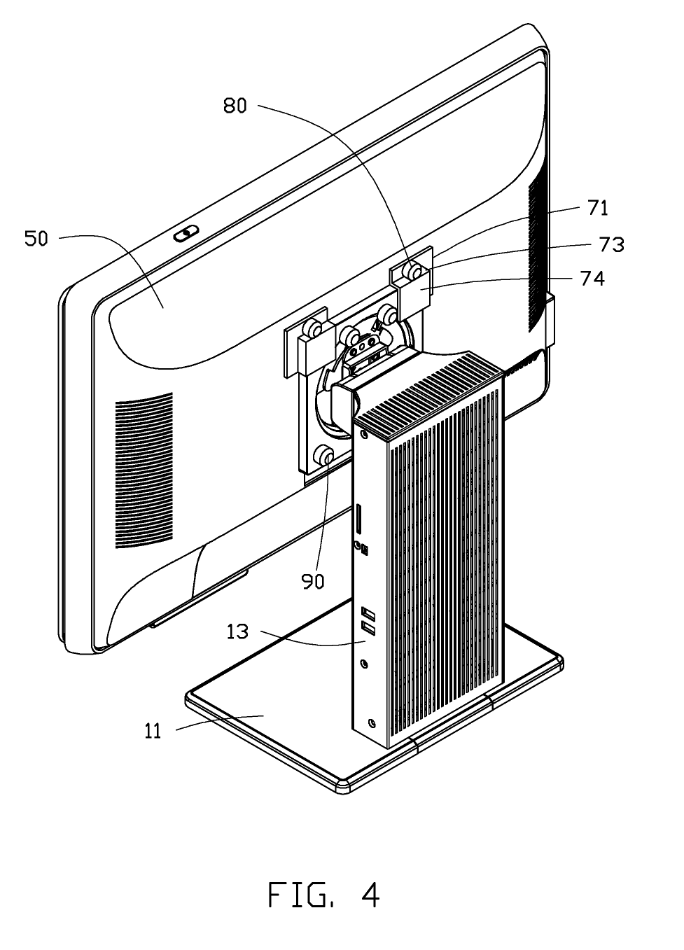

Referring to the FIGS. 3-5, in assembly, the retaining holes 711 of the positioning components 70 are aligned with the fixing holes 53 of the enclosure 50. A plurality of fixing members 80 is received in the retaining holes 711 and the corresponding fixing holes 53, to secure the positioning components 70 to the enclosure 50. The enclosure 50 is moved downwards, until two corners of the mounting member 30 are received in the accommodating spaces 75 of the positioning components 70. Then, the first connecting portion 72 abuts a first edge of the mounting member 30, and the second connecting portion 73 abuts a second opposite edge of the mounting member 30. The first and second mounting holes 31, 32 are aligned with the first and second securing holes 51, 52. Four fastening components 90 are received in the first and second mounting holes 31, 32 and the first and second securing holes 51, 52. Thus, the enclosure 50 is secured to the mounting member 30. In one embodiment, a washer (not shown) is attached to each fastening component 90, for increasing a friction between the fastening component 90 and the mounting member 30.

In disassembly, the four fastening components 90 are removed from the first and second mounting holes 31, 32 and the first and second securing holes 51, 52. The enclosure 50 is moved upwards, until the two corners of the mounting member 30 disengaged from the accommodating space 75 of the positioning component 70. Therefore, the enclosure 50 is removed from the supporting device 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
a supporting device;
a mounting member attached to the supporting device;
an enclosure; and
a positioning component comprising a first connecting portion, a second connecting portion, and a clipping portion connected to the first connecting portion and the second connecting portion; and the first connecting portion, the second connecting portion and the clipping portion define an accommodating space;
wherein the positioning component is attached to the enclosure, and a corner of the mounting member is received in the accommodating space of the positioning component, for preventing the enclosure from disengaging from the mounting member.

2. The electronic device of claim 1, wherein the positioning component comprises a securing portion, and the securing portion is substantially perpendicular to the first connecting portion and the second connecting portion.

3. The electronic device of claim 2, wherein the clipping portion is substantially perpendicular to the first connecting portion and the second connecting portion, and substantially parallel to the securing portion.

4. The electronic device of claim 1, wherein the first connecting portion is substantially perpendicular to the second connecting portion.

5. The electronic device of claim 1, wherein the first connecting portion abuts a first edge of the mounting member when the corner is received in the accommodating space, and the second connecting portion abuts a second edge of the mounting member when the corner is received in the accommodating space.

6. The electronic device of claim 1, wherein the supporting device comprises abase and a shaft; and the shaft is substantially perpendicular to the base.

7. The electronic device of claim 6, wherein an extending portion extends from a top end of the shaft, and the mounting member is mounted to the extending portion.

8. An electronic device comprising:
a supporting device;
a mounting member attached to the supporting device;
a enclosure securing a plurality of electronic components; and
a positioning component, attached to the enclosure, comprising a first connecting portion and a second connecting portion, an accommodating space is defined between the enclosure and the positioning component;
wherein the mounting member is engaged in the accommodating space, the first connecting portion abuts a first edge of the mounting member, and the second connecting portion abuts a second opposite edge of the mounting member, for securing the enclosure to the mounting member.

9. The electronic device of claim 8, wherein the positioning component further comprises a clipping portion; and the clipping portion, the first connecting portion and the second connecting portion together form the accommodating space.

10. The electronic device of claim 9, wherein the positioning component comprises a securing portion, and the securing portion is substantially perpendicular to the first connecting portion and the second connecting portion.

11. The electronic device of claim 10, wherein the clipping portion is substantially perpendicular to the first connecting portion and the second connecting portion, and the clipping portion is substantially parallel to the securing portion.

12. The electronic device of claim 10, wherein the first connecting portion is substantially perpendicular to the second connecting portion.

13. The electronic device of claim 8, wherein the supporting device comprises a base and a shaft, and the shaft is substantially perpendicular to the base.

14. The electronic device of claim 13, wherein an extending portion extends from a top end of the shaft, and the mounting member is mounted to the extending portion.
